(19) United States
(12) Patent Application Publication
(10) Pub. No.: US 2024/0074160 A1
(43) Pub. Date: Feb. 29, 2024

(54) INTEGRATION OF MEMORY ARRAY WITH PERIPHERY

(71) Applicant: Micron Technology, Inc., Boise, ID (US)

(72) Inventors: Shivani Srivastava, Boise, ID (US); Russell Allen Benson, Boise, ID (US); Raghunath Singanamalla, Boise, ID (US); Jaydeb Goswami, Boise, ID (US)

(21) Appl. No.: 18/236,566

(22) Filed: Aug. 22, 2023

Related U.S. Application Data
(60) Provisional application No. 63/401,937, filed on Aug. 29, 2022.

(51) Int. Cl. H10B 12/00

(52) U.S. Cl. CPC H10B 12/485; H10B 12/05; H10B 12/482

(57) ABSTRACT

A variety of applications can include apparatus having a memory device structured from integrated processing of a memory array of the memory device with a periphery to the memory array. The memory device can be implemented with transistors formed in the periphery, where metal gates of the transistors are structured without polysilicon regions between the metal gates and metal contacts for the metal gates. The integrated processing can provide step height reduction between the memory array and the periphery to the memory array of a memory device, with the elimination of polysilicon on the gate stack of transistors in the periphery. The step height reduction in the memory device can lower overlap capacitance.

### PRIORITY APPLICATION

This application claims the benefit of priority to U.S. Provisional Application Ser. No. 63/401,937, filed Aug. 29, 2022, which is incorporated herein by reference in its entirety.

### FIELD OF THE DISCLOSURE

Embodiments of the disclosure relate generally to memory systems, and more specifically, to memory devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates portions of an architecture of a memory device having a memory array region and a periphery to the memory array region after common processing of a metal digit line in the memory array region and a metal contact in the periphery, according to various embodiments.

FIG. 2 illustrates portions of another architecture of a memory device having a memory array region and a periphery to the memory array region after common processing of a metal digit line in the memory array region and a metal contact in the periphery, according to various embodiments.

FIGS. 3-14 illustrate an example process flow of forming a metal conductive region to a memory array region of a memory device and to a periphery of the memory array region of the memory device, according to various embodiments.

FIG. 15 illustrates an alternative process stage to the stage of FIG. 14 in the process flow of FIGS. 3-14, according to various embodiments.

FIG. 16 is a schematic of an example dynamic random-access memory device that can include an architecture having a memory array region and a periphery to the memory array after common processing of metal digit lines in the memory array region and metal contacts in the periphery, according to various embodiments.

FIG. 17 is a flow diagram of features of an example method of an integrating process flow of a memory array region and a periphery to the memory array region, according to various embodiments.

FIG. 18 is a flow diagram of features of another example method of an integrating process flow of a memory array region and a periphery to the memory array region, according to various embodiments.

FIG. 19 is a block diagram illustrating an example of a machine upon which one or more embodiments of one or more memory components may be implemented, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Traditional process flows for memory devices, such as DRAMs, utilize the same metallization for complementary metal-oxide-semiconductor (CMOS) devices in the periphery to a memory array and a memory array digit line in the memory array region. The same metallization, for example, can consist of barrier metals to a main conductor, where the barrier metals are designed for both CMOS devices in the periphery and the memory array. The same metallization used in traditional process flows for DRAMs in the periphery to a memory array and the memory array digit line can consist, for example, of barrier metal to a main conductor of tungsten (W), where the barrier metal includes titanium (Ti)/tungsten nitride (WN)/tungsten silicide (WSix). With respect to the barrier metal, Ti can form a titanium silicide (TiSix) layer with underlying polycrystalline silicon (polysilicon), while WN protects against Ti outdiffusion to the WSix and W layers. The WSix serves as a template for W to form low resistivity scaling. As DRAM scales to future designs, structural characteristics between array and periphery may no longer be the same.

A memory device, such as but is not limited to a DRAM device, can use transistors in the periphery region to the memory array region of the memory devices, where the structural relationship of the transistors to the memory array region can affect operation of the memory device. Typically, CMOS technology for such transistors, implementing a conventional polysilicon gate and a silicon oxynitride (SiON) gate dielectric, uses doped polysilicon for work function (WF) control with the n-type transistor and the p-type transistor of the CMOS device doped separately. The work function corresponds to a minimum amount of energy needed to remove an electron from a solid to a point in a vacuum immediately outside the solid surface.

With scaling of memory array dimensions, lower capacitance of digit lines, for example bit lines, can become critical for read/write timing associated with memory array access and for signal margin of sense amplifiers of the memory device. One approach to lower digit line capacitance is to reduce the metal conductor height of the digit line. However, with integration of fabrication processing of the memory array region and the periphery region of DRAM device, for example, DRAM integration is challenged due to step height difference between the memory array region and the periphery region.

In various embodiments, integrated processing of a memory array of a memory device with a CMOS periphery can be implemented with transistors formed in the periphery without polysilicon on a metal gate of the transistors. Such an integrated processing provides a skip polysilicon flow in forming the transistor in the memory periphery using CMOS technology. Such transistors in the periphery can be implemented with a high-k metal gate (HKMG). A HKMG is a gate structure having a metal gate located on a high-k dielectric, where a high-k dielectric is a dielectric having a dielectric constant greater than that of silicon dioxide (3.7-3.9). Herein, a high-k dielectric is a dielectric having a dielectric constant greater than 3.9. The high-k dielectric in the HKMG can be located on a thin layer of silicon oxide above a channel structure. A gate located on a gate dielectric above a channel structure of a transistor along with the gate dielectric can be referred to as a gate stack. A HKMG can provide a high performance CMOS device. Use of a HKMG can avoid the use of polysilicon on the gate stack, since a WF can be determined by the dipole of WF shifters. WF shifters are elements that can be incorporated in a thin high-k dielectric, where a WF shift can be achieved by diffusing such atoms into the thin high-k dielectric to create dipoles close to the channel, shifting the WF and, hence, the threshold voltage (V_{T}) of the transistor. Eliminating polysilicon on the gate stack of transistors in CMOS devices in the periphery to the memory array of a memory device can lower overlap capacitance, which can improve alternating current (AC) performance and operational speed of the memory device. Embodiments of an integration flow skipping implementation of polysilicon on the gate stack can provide improved step height reduction, which can provide improved yield and cost reduction.

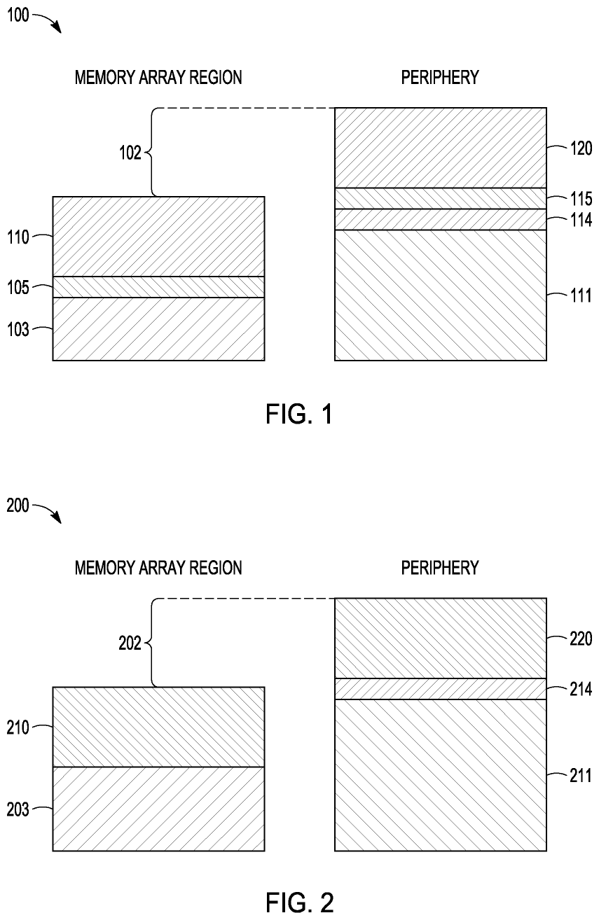

FIG. 1 illustrates portions of an architecture 100 of a memory device having a memory array region and a periphery to the memory array region after common processing of a metal digit line 110 in the memory array region and a metal contact 120 in the periphery. The metal contact 120 can be a metal contact to a transistor, such as but is not limited to a transistor in a CMOS device, in the periphery. The metal digit line 110 is separated from a dielectric 103 by a single metal barrier 105 in the memory array region, while the metal contact 120 is separated from a metal gate 111 by two metal barriers 115 and 114. Metal gate 111 can be a HKMG of a transistor, which transistor can be, but is not limited to, a p-channel MOS of a CMOS device.

In a non-limiting example, architecture 100 can include the periphery structure with W used as metal contact 120, WSix used as metal barrier 115, and WSiN used as metal barrier 114. Metal gate 111 can be a HKMG. The memory array region of architecture 100 can include W used as metal digit line 110 and WSix used as metal barrier 105. There is an array to periphery (A/P) step height 102 between a top level of metal digit line 110 in the memory array region and a top level of metal contact 120 in the periphery. With metal digit line 110 having a height of 14 nm, metal barrier 105 having a height of 3 nm, and dielectric 103 having a height of 10 nm in the memory array region; and with metal contact 120 having a height of 14 nm, metal barrier 115 having a height of 3 nm, metal barrier 114 having a height of 3 nm, and metal gate 111 having a height of 19 nm; the A/P step height 102 is 12 nm. Other heights can be implemented. With respect to some conventional architectures and processing, architecture 100 includes removal of polysilicon from above the gate structure in the periphery to the memory array region, removal of Ti and WN barrier metals in the memory array region and the periphery, and addition of WSiN to the metal barriers to the gate structure in the periphery.

Metal digit line 110, which with metal barrier 105 runs on dielectric 103 at the top level of and along dielectric 103, is one of a number of digit lines on dielectric 103. With digit lines running parallel on dielectric 103, there is a digit line capacitance between digit lines. Architecture 100 provides for reduced digit line capacitance, relative to a conventional architecture, due to the reduced height of the combination of metal digit line 110 and metal barrier 105 provided by limiting the number of metal barriers between metal digit line 110 and dielectric 103 to one metal barrier.

FIG. 2 illustrates an architecture 200 of a memory device having a memory array region and a periphery to the memory array region after common processing of a metal digit line 210 in the memory array region and a metal contact 220 in the periphery. The metal contact 220 can be a metal contact to a transistor in the periphery, such as but is not limited to a transistor in a CMOS device in the periphery. The metal digit line 210 is located directly on a dielectric 203 and is not separated from dielectric 203 by any metal barrier in the memory array region, while the metal contact 220 is separated from a metal gate 211 by metal barrier 214. Metal gate 211 can be a HKMG of a transistor, which transistor can be, but is not limited to, a p-channel MOS of a CMOS device. The high-k dielectric of then HKMG can be located on a thin layer of silicon oxide.

In a non-limiting example, architecture 200 can include the periphery structure with W used as metal contact 220 and WSiN used as metal barrier 214. Metal gate 211 can be a HKMG. The memory array region of architecture 200 can include W used as metal digit line 210. There is an A/P step height 202 between a top level of metal digit line 210 in the memory array region and a top level of metal contact 220. With metal digit line 210 having a height of 14 nm and dielectric 203 having a height of 10 nm in the memory array region; and with metal contact 220 having a height of 14 nm, metal barrier 214 having a height of 3 nm, and metal gate 211 having a height of 19 nm; the step height 202 is 26 nm. Other heights can be implemented. With respect to some conventional architectures and processing, architecture 200 includes removal of polysilicon from above the gate structure in the periphery to the memory array region, removal of Ti, WN, and WSix barrier metals in the memory array region and the periphery, and addition of WSiN to the metal barriers to the gate structure in the periphery.

Metal digit line 210 runs on the top level of and along dielectric 203 and is one of a number of digit lines on dielectric 203. With digit lines running parallel on dielectric 203, there is a digit line capacitance between digit lines. Architecture 200 provides for reduced digit line capacitance, relative to a conventional architecture, due to the reduced height of metal digit line 210 on dielectric 203 provided by directly placing metal digit line 210 on dielectric 203.

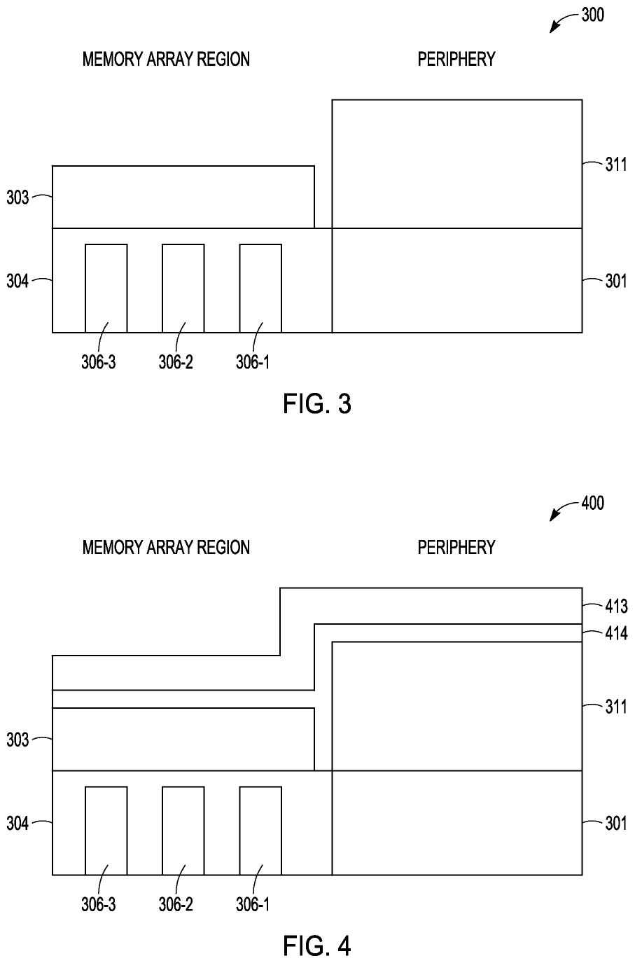

FIGS. 3-14 illustrate an embodiment of an example process flow of forming a metal conductive region to a memory array region of a memory device and to a periphery of the memory array region of the memory device, in which use of a polysilicon region on a gate structure in the periphery has been eliminated.

FIG. 3 illustrates a cross-sectional view of a structure 300, having a memory array region and a periphery, as a intermediate structure in forming a memory device. The memory array region includes an interlayer dielectric (ILD) 303 placed on another ILD 304, in which silicon regions 306-3, 306-2, and 306-1 are located. Though three silicon regions are shown, more or less than three silicon regions can be formed. For a memory array, such silicon regions can be significantly more in number than three. ILD 303 can include silicon oxide, such as SiO₂, silicon nitride, such as Si₃N₄, or other appropriate dielectric material. The periphery includes a metal gate 311 on a substrate region 301. Metal gate 311 can be a HKMG and substrate region 301 can be a silicon substrate region. Example heights for components of structure 300 can include, but are not limited to, ILD 303 having a height of 5-20 nm and metal gate 311 having a height of 15-25 nm. Structure 300 provides a starting structure for the process flow associated with FIGS. 3-14.

FIG. 4 illustrates a cross-sectional view of a structure 400, having a memory array region and a periphery, after processing structure 300 of FIG. 3. A metal barrier 414 has been formed on metal gate 311 in the periphery and on ILD 303 in the memory array region, with a protective layer 413 formed on and above metal barrier 414 to protect metal barrier 414 during memory array processing. Protective layer 413 can be an oxide layer. Metal barrier 414 can be formed by a suitable process such as by a deposition process including but is not limited to chemical vapor deposition (CVD), atomic layer deposition (ALD), or other deposition process. Other processes can be used. Metal barrier 414 can include a WSiN barrier metal. In other embodiments, metal barrier 414 can include other barrier metals or additional barrier metals. Metal gate 311 can include a metal, such as but is not limited to, TiN on which metal barrier 414 can be arranged. The WSiN barrier metal can be formed as a WSiN layer. Metal barrier 414 will only remain in the periphery at the completion of the process flow associated with FIGS. 3-14.

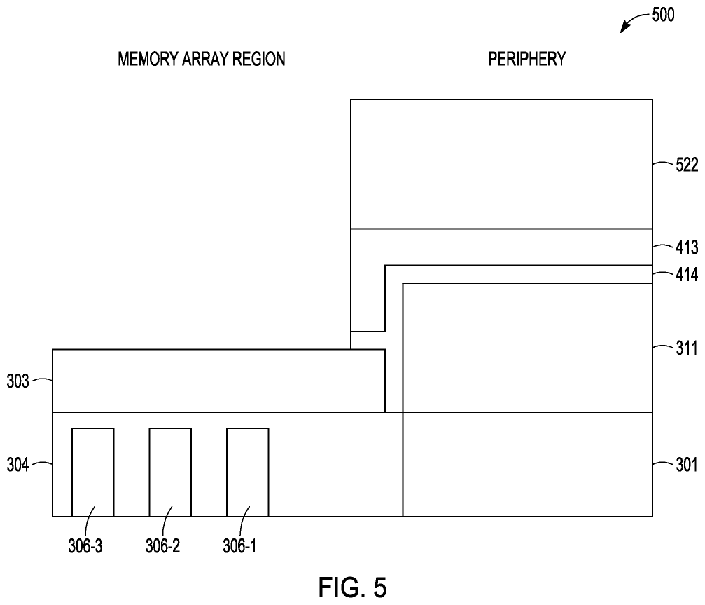

FIG. 5 illustrates a cross-sectional view of a structure 500, having a memory array region and a periphery, after processing structure 400 of FIG. 4. Patterning and etching has been applied to structure 400 to strip metal barrier 414 and protective layer 413 from the memory array region using a photoresist 522. The memory array region has been cleaned to clear metals of metal barrier 414 from the memory array region. Photoresist 522 remains on metal barrier 414 in the periphery, where photoresist 522 protected the periphery during the removal of metal barrier 414 and protective layer 413.

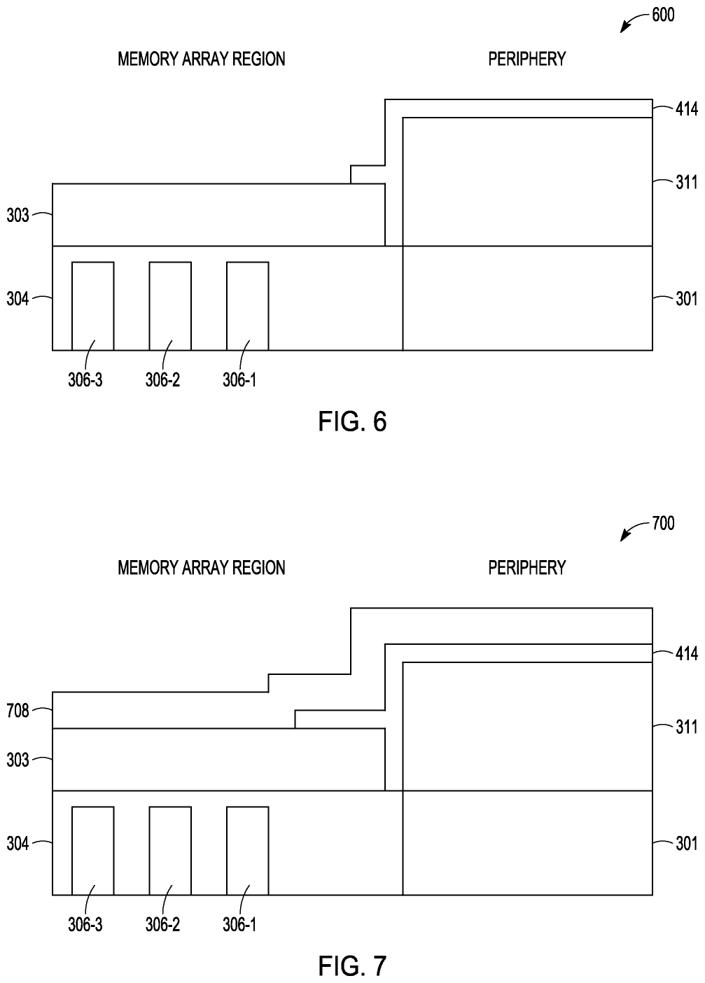

FIG. 6 illustrates a cross-sectional view of a structure 600, having a memory array region and a periphery, after processing structure 500 of FIG. 5. Photoresist 522 and protective layer 413 have been removed from structure 500.

FIG. 7 illustrates a cross-sectional view of a structure 700, having a memory array region and a periphery, after processing structure 600 of FIG. 6. An ILD 708 has been formed on ILD 303 in the memory array region and on metal barrier 414 in the periphery. ILD 708 can be a silicon oxide region, a silicon nitride region, or other suitable dielectric. ILD 708 can be formed using an appropriate deposition technique suitable for the dielectric formed for ILD 708. ILD 708 can be formed having a thickness from about 10 nm to 20 nm. ILD 708 can be formed having other thicknesses. ILD 708 provides an ILD protection for further processing.

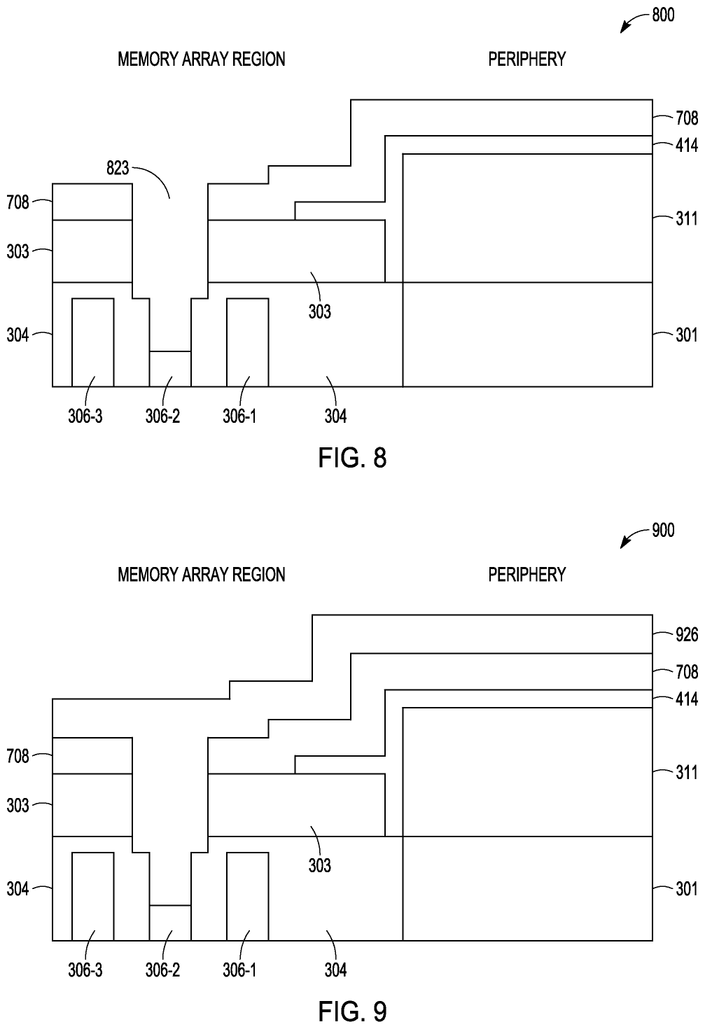

FIG. 8 illustrates a cross-sectional view of a structure 800, having a memory array region and a periphery, after processing structure 700 of FIG. 7. Selected regions have been etched, removing portions of ILD 708, ILD 303, and silicon region 306-2, resulting in an opening 823. The etching process can be formed in a number of procedures. For example a photoresist or carbon patterning can have been applied to structure 700, where the pattern corresponds to an array of digit line contacts for the memory array to provide selected openings for forming the digit line contacts. Though not shown, the pattern corresponding to the array of digit line contacts can include a number of other silicon regions partially etched with an opening above the silicon regions. The surfaces of opening 823 can have been cleaned for further processing.

FIG. 9 illustrates a cross-sectional view of a structure 900, having a memory array region and a periphery, after processing structure 800 of FIG. 8. A polysilicon 926 has been formed on the surface of ILD 708 in the memory array region and in the periphery of structure 800 and in opening 823 above silicon region 306-2. Polysilicon 926 can be formed using an appropriate deposition technique suitable for depositing polysilicon on the surfaces of ILDs and surfaces within openings. Portions of polysilicon 926 will only remain in data line contacts in the memory array region at the completion of the process flow associated with FIGS. 3-14.

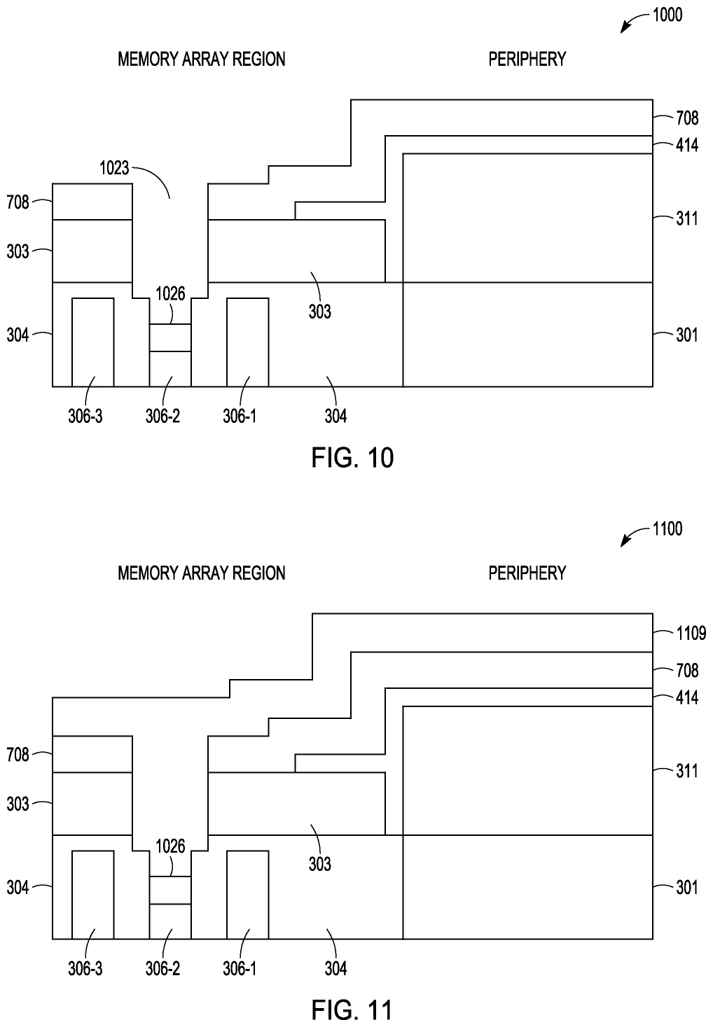

FIG. 10 illustrates a cross-sectional view of a structure 1000, having a memory array region and a periphery, after processing structure 900 of FIG. 9. Polysilicon 926 in structure 900 has been etched back, leaving a polysilicon plug 1026 on silicon region 306-2. Top surfaces of ILD 708 and surfaces of ILDs 708, 303, and 304 of formed opening 1023 are exposed for further processing.

FIG. 11 illustrates a cross-sectional view of a structure 1100, having a memory array region and a periphery, after processing structure 1000 of FIG. 10. A metal barrier 1109 has been formed on the surfaces of structure 1000 including on the top surface of ILD 708, surfaces of ILDs 708, 303, and 304 that defined opening 1023, and on surface of polysilicon plug 1026. Opening 1023 has been filled with metal barrier 1109. Portions of metal barrier 1109 are to be used as barrier metals in the memory array. Metal barrier 1109 can be formed by a suitable process such as by a deposition process including but is not limited to CVD, ALD, or other deposition process. Other processes can be used. Metal barrier 1109 can include multiple metals such as, but is not limited to, WN and Ti along with TiN or W. Metal barrier 1109 can be formed as a Ti barrier metal on the surfaces of structure 1000 with a WN barrier metal on the Ti barrier and with TiN barrier metal or W barrier metal on the WN barrier metal. Ti, WN, TiN, and W barrier metals can each be formed as barrier metal layers. Portions of metal barrier 1109 will only remain in the memory array region at the completion of the process flow associated with FIGS. 3-14.

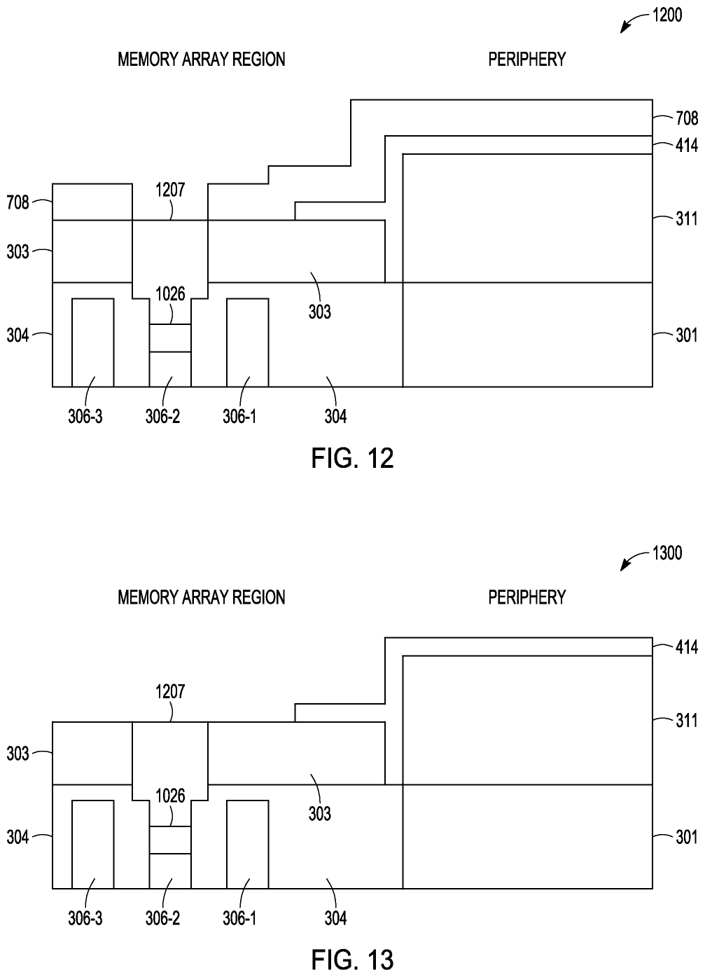

FIG. 12 illustrates a cross-sectional view of a structure 1200, having a memory array region and a periphery, after processing structure 1100 of FIG. 11. Metal barrier 1009 has been etched back leaving a digit line contact 1207 on and contacting polysilicon plug 1026 on silicon region 306-2.

FIG. 13 illustrates a cross-sectional view of a structure 1300, having a memory array region and a periphery, after processing structure 1200 of FIG. 12. ILD 708 has been removed in the memory array region and in the periphery. A top surface of ILD 303 and the surface of digit line contact 1207 are exposed in the memory array region and the surface of metal barrier 414 is exposed in the periphery.

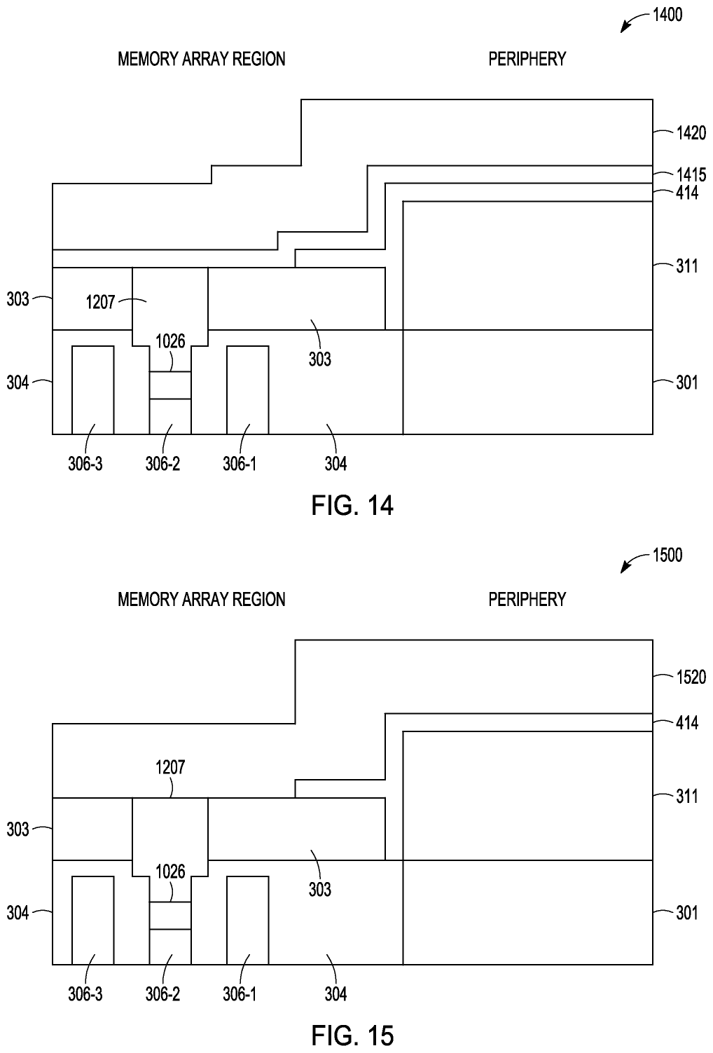

FIG. 14 illustrates a cross-sectional view of a structure 1400, having a memory array region and a periphery, after processing structure 1300 of FIG. 13. A barrier metal 1415 has been formed on the surface of structure 1300 of FIG. 13 in both the memory array region and in the periphery, including on the top surface of digit line contact 1207 that is on and contacting polysilicon plug 1026 on silicon region 306-2. Barrier metal 1415 can be formed by a suitable process such as by a deposition process including but is not limited to CVD, ALD, or other deposition process. Other processes can be used. Barrier metal 1415 can be formed as WSix. Barrier metal 1415 can be formed having a thickness of about 2.5 nm. Barrier metal 1415 can be formed with other thicknesses.

A metal 1420 has been formed on the surface of barrier metal 1415 in both the memory array region and in the periphery. Metal 1420 can be formed by a suitable process such as by a deposition process including but is not limited to CVD, ALD, or other deposition process. Other processes can be used. Metal 1420 can be formed as W. Metal 1420 can be formed having a thickness of about 10 nm to about 30 nm. Metal 1420 can be formed with other thicknesses. In the periphery, metal 1420 is a metal contact to the transistor having metal gate 311, where barrier metal 1415 and metal barrier 414 couple metal gate 311 to metal 1420. In the memory array region, metal 1420 is a digit line having barrier metal 1415 as a single barrier metal above ILD 303, where barrier metal 1415 couples the digit line to the digit line contact 1207 that is on and contacting polysilicon plug 1026 on silicon region 306-2.

Structure 1400 can be further processed such that metal 1420 in the periphery is separated from metal 1420 in the memory array region. Structure 1400 with the separated metal 1420 has a single barrier metal for coupling from the separated metal 1420 to the digit line in the memory array region, which is a structure similar to architecture 100 of FIG. 1. Depending on the memory device design and conductive contact architecture for the memory device, metallic materials other than those discussed above can be used in similar approaches.

FIG. 15 illustrates an alternative process stage to the stage of FIG. 14 in the process flow of FIGS. 3-14. FIG. 15 illustrates a cross-sectional view of a structure 1500, having a memory array region and a periphery, after processing structure 1300 of FIG. 13. A metal 1520 has been formed on the surface of metal barrier 414 in the periphery and on the top surface of ILD 303 and the top surface of digit line contact 1207, which is on and contacting polysilicon plug 1026 on silicon region 306-2, in the memory array region. Metal 1520 can be formed by a suitable process such as by a deposition process including but is not limited to CVD, ALD, or other deposition process. Other processes can be used. Metal 1520 can be formed as W. Metal 1520 can be formed having a thickness of about 10 nm to about 30 nm. Metal 1520 can be formed with other thicknesses. In the periphery, metal 1520 is a metal contact to the transistor having metal gate 311, where metal barrier 414 couples metal gate 311 to metal 1520. In the memory array region, metal 1520 is a digit line coupled to the digit line contact 1207 that is on and contacting polysilicon plug 1026 on silicon region 306-2.

Structure 1500 can be further processed such that metal 1520 in the periphery is separated from metal 1520 in the memory array region. Structure 1500 with the separated metal 1520 has a direct coupling from the separated metal 1520 to the digit line in the memory array region, which is a structure similar to architecture 200 of FIG. 2. Depending on the memory device design and conductive contact architecture for the memory device, metallic materials other than those discussed above can be used in similar approaches.

Various deposition techniques for components of structures 300-1500 in the process flow of FIGS. 3-15 can be used that are typical for the material being formed, the dimensions of the material being formed, and the architecture in which the material is being formed. Selective etching can be used to remove selected regions in the processing discussed with respect to FIGS. 3-14. Selective etching is a process in which one or more materials are removed from a structure, while one or more other materials remain in the structure with no or little removal. Selective etching can depend on the material to be etched, the material not to be etched, the etchant employed, and the method for etching. Types of etching include wet etching and dry etching, where each of these two basic methods can include a number of different etching procedures. In addition, conventional masking techniques, providing protective regions in the processing, can be used in removal of selected regions in connecting digit lines to digit line contacts in the memory array.

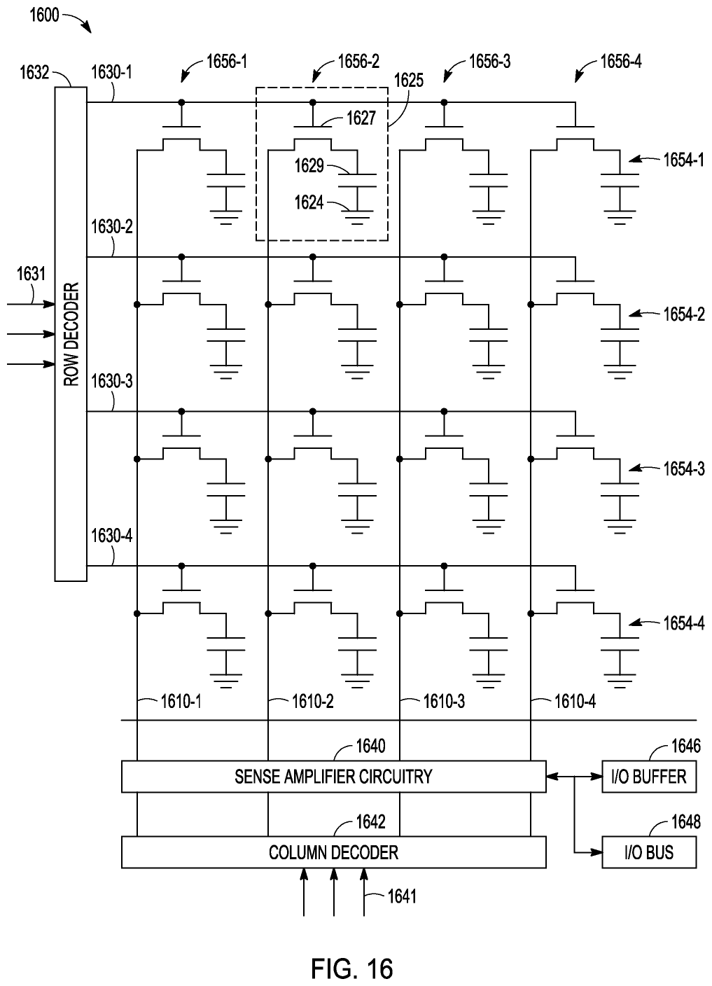

FIG. 16 is a schematic of an embodiment of an example DRAM device 1600 that can include an architecture having a memory array region and a periphery to the memory array after common processing of metal digit lines in the memory array region and metal contacts in the periphery as taught herein. DRAM device 1600 includes an array of memory cells 1625 (only one being labeled in FIG. 16 for ease of presentation) arranged in rows 1654-1, 1654-2, 1654-3, and 1654-4 and columns 1656-1, 1656-2, 1656-3, and 1656-4. For simplicity and ease of discussion, the array is shown in only two dimensions, but the array can be extended into the third dimension. Further, while only four rows 1654-1, 1654-2, 1654-3, and 1654-4 and four columns 1656-1, 1656-2, 1656-3, and 1656-4 of four memory cells are illustrated, DRAM devices like DRAM device 1600 can have significantly more memory cells 1625 (e.g., tens, hundreds, or thousands of memory cells) per row or per column.

Each memory cell 1625 can include a single transistor 1627 and a single capacitor 1629, which is commonly referred to as a 1T1C (one-transistor-one capacitor cell). One plate of capacitor 1629, which can be termed the “node plate,” is connected to the drain terminal of transistor 1627, whereas the other plate of the capacitor 1629 is connected to ground 1624. Each capacitor 1629 within the array of 1T1C memory cells 1625 typically serves to store one bit of data, and the respective transistor 1627 serves as an access device to write to or read from storage capacitor 1629.

The transistor gate terminals within each row of rows 1654-1, 1654-2, 1654-3, and 1654-4 are portions of respective access lines 1630-1, 1630-2, 1630-3, and 1630-4 (for example, word lines), and the transistor source terminals within each of columns 1656-1, 1656-2, 1656-3, and 1656-4 are electrically connected to respective digit lines 1610-1, 1610-2, 1610-3, and 1610-4 (for example bit lines). A row decoder 1632 can selectively drive the individual access lines 1630-1, 1630-2, 1630-3, and 1630-4, responsive to row address signals 1631 input to row decoder 1632. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier circuitry 1640, which can transfer bit values between the memory cells 1625 of the selected row of the rows 1654-1, 1654-2, 1654-3, and 1654-4 and input/output buffers 1646 (for write/read operations) or external input/output data buses 1648.

A column decoder 1642 responsive to column address signals 1641 can select which of the memory cells 1625 within the selected row is read out or written to. Alternatively, for read operations, the storage capacitors 1629 within the selected row may be read out simultaneously and latched, and the column decoder 1642 can then select which latch bits to connect to the output data bus 1648. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

Digit lines 1610-1, 1610-2, 1610-3, and 1610-4 can be constructed as metal digit lines in a process flow with a metal contact to a device or circuit in the periphery that can include sense amplifier circuitry 1640, where the metal is the same for digit lines 1610-1, 1610-2, 1610-3, and 1610-4 and the metal contact and is formed at the same time in the fabrication process flow. Digit lines 1610-1, 1610-2, 1610-3, and 1610-4 can be structured with at most one metal barrier to each respective digit line contacts to which digit lines 1610-1, 1610-2, 1610-3, and 1610-4 are coupled, while the metal contacts in the periphery have multiple metal barriers to a gate of a transistor. In various embodiments, the metal contacts in the periphery can have at most two metal barriers to a gate of a transistor. The number (zero or positive integer) of metal barriers in the memory array and the number (zero or positive integer) of metal barriers to gates in the periphery can include the number of metal barriers in the memory array region being larger than the number of metal barriers to gates in the periphery.

DRAM device 1600 may be implemented as an integrated circuit within a package that includes pins for receiving supply voltages (e.g., to provide the source and gate voltages for the transistors 1627) and signals (including data, address, and control signals). FIG. 16 depicts DRAM device 1600 in simplified form to illustrate basic structural components, omitting many details of the memory cells 1625 and associated access lines 1630-1, 1630-2, 1630-3, and 1630-4 and digit lines 1610-1, 1610-2, 1610-3, and 1610-4 as well as the peripheral circuitry. For example, in addition to the row decoder 1632 and column decoder 1642, sense amplifier circuitry 1640, and buffers 1646, DRAM device 1600 may include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 1654-1, 1654-2, 1654-3, and 1654-4 and columns 1656-1, 1656-2, 1656-3, and 1656-4 of memory cells 1625 are arranged along a single horizontal plane (i.e., a plane parallel to the layers) of the semiconductor substrate, e.g., in a rectangular lattice with mutually perpendicular horizontal access lines 1630-1, 1630-2, 1630-3, and 1630-4 and digit lines 1610-1, 1610-2, 1610-3, and 1610-4. In 3D DRAM arrays, the memory cells 1625 are arranged in a 3D lattice that encompasses multiple vertically stacked horizontal planes corresponding to multiple device tiers of a multi-tier substrate assembly, with each device tier including multiple parallel rows of memory cells 1625 whose transistor gate terminals are connected by horizontal access lines such as access lines 1630-1, 1630-2, 1630-3, and 1630-4. A “device tier,” as used herein, may include multiple layers (or levels) of materials, but forms the components of memory devices of a single horizontal tier of memory cells. Digit lines 1610-1, 1610-2, 1610-3, and 1610-4 can extend vertically through all or at least a vertical portion of the multi-tier structure, and each of the digit lines 1610-1, 1610-2, 1610-3, and 1610-4 can connect to the transistor source terminals of respective vertical columns 1656-1, 1656-2, 1656-3, and 1656-4 of associated memory cells 1625 at the multiple device tiers. Such a 3D configuration of memory cells enables further increases in bit density compared with 2D arrays.

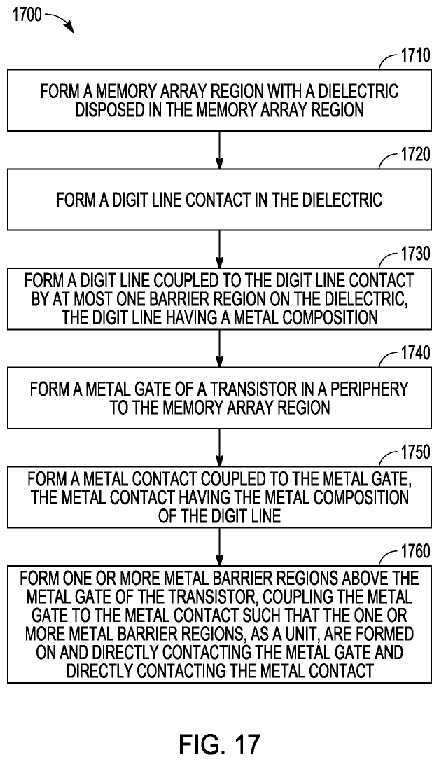

FIG. 17 is a flow diagram of features of an embodiment of an example method 1700 of forming a memory device. At 1710, a memory array region is formed with a dielectric disposed in the memory array region. At 1720, a digit line contact is formed in the dielectric. At 1730, a digit line is formed coupled to the digit line contact by at most one barrier region on the dielectric. The digit line can have a metal composition. At 1740, a metal gate of a transistor is formed in a periphery to the memory array region. At 1750, a metal contact is formed coupled to the metal gate of the transistor, where the metal contact has the metal composition of the digit line. Forming the metal contact can be performed in a common fabrication procedure with forming the digit line. At 1760, one or more metal barrier regions are formed above the metal gate, coupling the transistor to the metal contact such that the one or more metal barrier regions, as a unit, are formed on and directly contacting the metal gate and directly contacting the metal contact.

Variations of method 1700 or methods similar to method 1700 can include a number of different embodiments that may be combined depending on the application of such methods and/or the architecture of systems in which such methods are implemented. Such methods can include forming the one or more metal barrier regions by forming two metal barrier regions. Forming the two metal barrier regions can include forming a first metal region of the two metal barrier regions before forming the digit line contact in the dielectric and forming a second metal region of the two metal barrier regions after forming the digit line contact in the dielectric.

Variations of method 1700 or methods similar to method 1700 can include forming the digit line and the metal contact using tungsten; forming the at most one barrier region by forming tungsten silicide extending above and from a top level of the dielectric; and forming the one or more metal barrier regions by forming tungsten silicon nitride and tungsten silicide. Variations can include forming the digit line by forming a tungsten digit line without a barrier region above a top level of the dielectric; and forming the one or more metal barrier regions by forming tungsten silicon nitride contacting the metal gate and the metal contact.

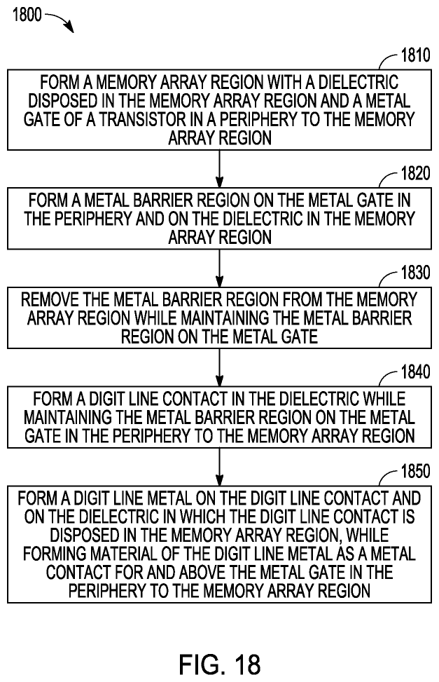

FIG. 18 is a flow diagram of features of an embodiment of an example method 1800 of forming a memory device. At 1810, a memory array region is formed with a dielectric disposed in the memory array region and a metal gate of a transistor is formed in a periphery to the memory array region. At 1820, a metal barrier region is formed on the metal gate in the periphery and on the dielectric in the memory array region. At 1830, the metal barrier region is removed from the memory array region while maintaining the metal barrier region on the metal gate. At 1840, a digit line contact is formed in the dielectric while maintaining the metal barrier region on the metal gate in the periphery to the memory array region. At 1850, a digit line metal is formed on the digit line contact and on the dielectric in which the digit line contact is disposed in the memory array region, while forming material of the digit line metal as a metal contact for and above the metal gate in the periphery to the memory array region.

Variations of method 1800 or methods similar to method 1800 can include a number of different embodiments that may be combined depending on the application of such methods and/or the architecture of systems in which such methods are implemented. Such methods can include forming a protective dielectric layer on the metal barrier region, with the metal barrier region on the metal gate of the transistor in the periphery and on the dielectric in the memory array region. A photoresist can be formed on a portion of the protective layer to provide an open pattern to the memory array region. The metal barrier region can be removed from the memory array region while maintaining the metal barrier region on the metal gate of the transistor. The patterned photoresist can be used in removing the metal barrier region.

Variations of method 1800 or methods similar to method 1800 can include forming the digit line contact by forming an opening in the dielectric in the memory array region, exposing a silicon region in the memory array region. Polysilicon can be formed in the opening to the silicon region, on the memory array region, and above the transistor in the periphery. The polysilicon can be removed from the memory array region and from above the transistor in the periphery such that a portion of the polysilicon remains on the silicon region. The digit line contact can be formed on and contacting the portion of the polysilicon that remains on the silicon region.

Variations of method 1800 or methods similar to method 1800 can include forming a second metal barrier region on the digit line contact, on the dielectric, and on the metal barrier region. The metal for the digit line and the metal contact can be formed on the second metal barrier region. The second metal barrier region can provide a barrier region on the dielectric in addition to providing another metal barrier region between the metal gate and the metal contact in the periphery.

The fabrication techniques used in methods 1700, 1800, or methods similar to methods 1700 and 1800 can use conventional techniques for removing material such as masking, etching, and other removal processes. The formation techniques can use conventional techniques for forming materials in semiconductor based memory devices. Formation techniques can include deposition processes such as, but is not limited to, chemical vapor deposition and atomic layer deposition.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but is not limited to, a microprocessor, a microcontroller, a graphics processor, a digital signal processor (DSP), or any other type of processor or processing circuit, including a group of processors or multi-core devices.

In various embodiments, a memory device can comprise a memory array region and a periphery to the memory array region. A dielectric can be disposed in the memory array region and a digit line contact can be disposed in the dielectric. A digit line can be coupled to the digit line contact by at most one barrier region on the dielectric, where the digit line has a selected metal composition. A transistor in the periphery to the memory array region can be coupled to a metal contact, where the metal contact has the selected metal composition of the digit line. One or more metal barrier regions can be located above a metal gate of the transistor, where the one or more metal barrier regions couple the transistor to the metal contact. The one or more metal barrier regions can be arranged, as a unit, on and directly contacting the metal gate and directly contacting the metal contact.

Variations of such a memory device and its features, as taught herein, can include a number of different embodiments and features that may be combined depending on the application of such memory devices, the format of such memory devices, and/or the architecture in which such memory devices are implemented. Features of such memory devices can include the digit line having a thickness equal to a thickness of the metal contact. The selected metal composition for the digit line and the metal contact can include tungsten.

Variations of such a memory device or its features can include the at most one barrier region, on the dielectric, having tungsten silicide extending above and from a top level of the dielectric, and the one or more metal barrier regions, on the metal gate, containing tungsten silicon nitride and tungsten silicide. The tungsten silicide can extend above the top level of the dielectric by, but is not limited to, about 3 nm, and the one or more metal barrier regions combined can extend above a top level of the metal gate by, but is not limited to, about 6 nm.

Variations of such a memory device or its features can include the digit line being a tungsten digit line without a barrier region above a top level of the dielectric coupling the tungsten digit line to the digit line contact. The one or more metal barrier regions in the periphery can include tungsten silicon nitride contacting the metal gate and the metal contact. The tungsten silicon nitride can have, but is limited to, a thickness of 3 nm.

Variations of such a memory device or its features can include a step height between a top level of the metal contact on the transistor in the periphery to a top level of the digit line in the memory array region being, but is limited to, about 12 nm. Variations of such a memory device or its features can include the transistor being a transistor of a CMOS device. The metal contact on the CMOS transistor can be coupled by the one or more regions to a high-k metal gate of the CMOS transistor.

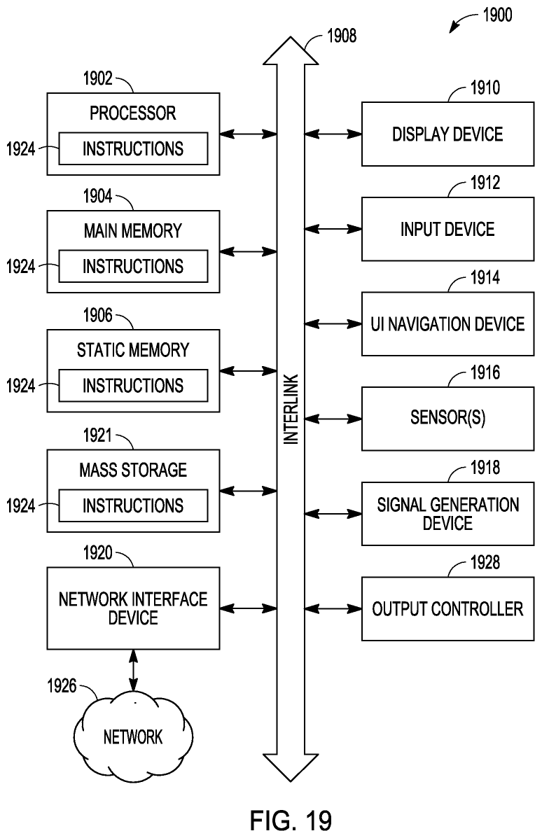

FIG. 19 illustrates a block diagram of an example machine 1900 having one or more embodiments of memory components discussed herein. In alternative embodiments, machine 1900 may operate as a standalone device or may be connected (e.g., networked) to other machines. In a networked deployment, machine 1900 may operate in the capacity of a server machine, a client machine, or both in server-client network environments. In an example, machine 1900 may act as a peer machine in peer-to-peer (P2P) (or other distributed) network environment. Machine 1900 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), other computer cluster configurations. Example machine 1900 can include one or more memory devices having structures as discussed with respect to architecture 100 of FIG. 1 or architecture 200 of FIG. 2.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry.

Machine (e.g., computer system) 1900 may include a hardware processor 1902 (e.g., a CPU, a GPU, a hardware processor core, or any combination thereof), a main memory 1904 and a static memory 1906, some or all of which may communicate with each other via an interlink (e.g., bus) 1908. Machine 1900 may further include a display unit 1910, an alphanumeric input device 1912 (e.g., a keyboard), and a user interface (UI) navigation device 1914 (e.g., a mouse). In an example, display unit 1910, input device 1912, and UI navigation device 1914 may be a touch screen display. Machine 1900 may additionally include a mass storage (e.g., drive unit) 1921, a signal generation device 1918 (e.g., a speaker), a network interface device 1920, and one or more sensors 1916, such as a global positioning system (GPS) sensor, compass, accelerometer, or other sensor. Machine 1900 may include an output controller 1928, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 1900 may include a machine-readable medium on which is stored one or more sets of data structures or instructions 1924 (for example, software or microcode) embodying or utilized by machine 1900. Instructions 1924 may also reside, completely or at least partially, within main memory 1904, within static memory 1906, within mass storage 1921, or within hardware processor 1902 during execution thereof by machine 1900. In an example, one or any combination of hardware processor 1902, main memory 1904, static memory 1906, or mass storage 1921 may constitute machine-readable medium. Machine-readable medium can be a single medium or multiple media (e.g., a centralized or distributed database, or associated caches and servers) configured to store one or more instructions 1924.

The term “machine-readable medium” may include any medium that is capable of storing instructions for execution by machine 1900 and that cause machine 1900 to perform any one or more of the techniques for which machine 1900 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 1924 (e.g., software, programs, microcode, an operating system (OS), etc.) or other data stored on mass storage 1921, can be accessed by memory 1904 for use by processor 1902. Memory 1904 (e.g., DRAM) is typically fast, but volatile, and thus a different type of storage than mass storage 1921 (e.g., an SSD), which is suitable for long-term storage, including while in an “off” condition. Instructions 1924 or data in use by a user or machine 1900 are typically loaded in memory 1904 for use by processor 1902. When memory 1904 is full, virtual space from mass storage 1921 can be allocated to supplement memory 1904; however, because mass storage 1921 is typically slower than memory 1904, and write speeds are typically at least twice as slow as read speeds, use of virtual memory can greatly reduce user experience due to storage device latency (in contrast to memory 1904, e.g., DRAM). Further, use of mass storage 1921 for virtual memory can greatly reduce the usable lifespan of mass storage 1921.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 1924 may further be transmitted or received over a communications network 1926 using a transmission medium via network interface device 1920 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 1920 may include one or more physical jacks (e.g., Ethernet, coaxial, or phone jacks) or one or more antennas to connect to the communications network 1926. In an example, network interface device 1920 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 1900, and includes digital or analog communications signals or other tangible medium to facilitate communication of such software.

The following are example embodiments of devices and methods, in accordance with the teachings herein.

An example memory device 1 can comprise: a memory array region; a dielectric disposed in the memory array region; a digit line contact disposed in the dielectric; a digit line coupled to the digit line contact by at most one barrier region on the dielectric, the digit line having a metal composition; a transistor in a periphery to the memory array region; a metal contact coupled to the transistor, the metal contact having the metal composition of the digit line; and one or more metal barrier regions above a metal gate of the transistor, coupling the transistor to the metal contact, the one or more metal barrier regions arranged as a unit on and directly contacting the metal gate and directly contacting the metal contact.

An example memory device 2 can include features of example memory device 1 and can include the digit line having a thickness equal to a thickness of the metal contact.

An example memory device 3 can include features of any features of the preceding example memory devices and can include the metal composition to include tungsten.

An example memory device 4 can include features of any of the preceding example memory devices and can include the at most one barrier region to include tungsten silicide extending above and from a top level of the dielectric, and the one or more metal barrier regions include tungsten silicon nitride and tungsten silicide.

An example memory device 5 can include features of example memory device 4 and any features of the preceding example memory devices and can include the tungsten silicide extending above the top level of the dielectric by about 3 nm and the one or more metal barrier regions combined extending above a top level of the metal gate by about 6 nm.

An example memory device 6 can include features of any of the preceding example memory devices and can include the digit line being a tungsten digit line without a barrier region above a top level of the dielectric coupling the tungsten digit line to the digit line contact, and the one or more metal barrier regions to include tungsten silicon nitride contacting the metal gate and the metal contact.

An example memory device 7 can include features of example memory device 6 and any features of the preceding example memory devices and can include the tungsten silicon nitride having a thickness of 3 nm.

An example memory device 8 can include features of any of the preceding example memory devices and can include a step height between a top level of the metal contact on the transistor in the periphery to a top level of the digit line in the memory array region being about 12 nm.

An example memory device 9 can include features of example memory device 8 and any features of the preceding example memory devices and can include the transistor being a transistor of a CMOS device.

An example memory device 10 can include features of example memory device 9 and any features of the preceding example memory devices and can include the metal gate being a high-k metal gate.

In an example memory device 11, any of the memory devices of example memory devices 1 to 10 may include memory devices incorporated into an electronic memory apparatus further comprising a host processor and a communication bus extending between the host processor and the memory device.

In an example memory device 12, any of the memory devices of example memory devices 1 to 11 may be modified to include any structure presented in another of example memory device 1 to 11.

In an example memory device 13, any of the memory devices of example memory devices 1 to 12 may be modified to include any structure presented in another of example memory device 1 to 12.

In an example memory device 14, any apparatus associated with the memory devices of example memory devices 1 to 13 may further include a machine-readable storage device configured to store instructions as a physical state, wherein the instructions may be used to perform one or more operations of the apparatus.

In an example memory device 15, any of the memory devices of example memory devices 1 to 14 may be operated in accordance with any of the methods of the above example methods 1 to 18.

An example method 1 of forming a memory device can comprise: forming a memory array region with a dielectric disposed in the memory array region; forming a digit line contact in the dielectric; forming a digit line coupled to the digit line contact by at most one barrier region on the dielectric, the digit line having a metal composition; forming a metal gate of a transistor in a periphery to the memory array region; forming a metal contact coupled to the metal gate, the metal contact having the metal composition of the digit line; and forming one or more metal barrier regions above the metal gate of the transistor, coupling the metal gate to the metal contact such that the one or more metal barrier regions, as a unit, are formed on and directly contacting the metal gate and directly contacting the metal contact.

An example method 2 of forming a memory device can include features of example method 1 of forming a memory device and can include forming the one or more metal barrier regions to include forming two metal barrier regions.

An example method 3 of forming a memory device can include features of example method 2 of forming a memory device and any of the preceding example methods of forming a memory device and can include forming the two metal barrier regions by forming a first metal region of the two metal barrier regions before forming the digit line contact in the dielectric and forming a second metal region of the two metal barrier regions after forming the digit line contact in the dielectric.

An example method 4 of forming a memory device can include features of any of the preceding example methods of forming a memory device can include forming the digit line being performed in a common fabrication procedure with forming the metal contact.

An example method 5 of forming a memory device can include features of any of the preceding example methods of forming a memory device and can include forming the digit line and the metal contact using tungsten; forming the at most one barrier region by forming tungsten silicide extending above and from a top level of the dielectric; and forming the one or more metal barrier regions by forming tungsten silicon nitride and tungsten silicide.

An example method 6 of forming a memory device can include features of any of the preceding example methods of forming a memory device and can include forming the digit line by forming a tungsten digit line without a barrier region above a top level of the dielectric; and forming the one or more metal barrier regions by forming tungsten silicon nitride contacting the metal gate and the metal contact.

In an example method 7, any of the example methods 1 to 6 of forming a memory device may be performed in forming an electronic memory apparatus further comprising a host processor and a communication bus extending between the host processor and the memory device.

In an example method 8, any of the example methods 1 to 7 of forming a memory device may be modified to include operations set forth in any other of method examples 1 to 7 of forming a memory device.

In an example method 9 of forming a memory device, any of the example methods 1 to 8 of forming a memory device may be implemented at least in part through use of instructions stored as a physical state in one or more machine-readable storage devices.

An example method 10 of forming a memory device can include features of any of the preceding example methods 1 to 9 of forming a memory device and can include performing functions associated with any features of example memory devices 1 to 15.

An example method 11 of forming a memory device can comprise: forming a memory array region with a dielectric disposed in the memory array region and a metal gate of a transistor in a periphery to the memory array region; forming a metal barrier region on the metal gate in the periphery and on the dielectric in the memory array region; removing the metal barrier region from the memory array region while maintaining the metal barrier region on the metal gate; forming a digit line contact in the dielectric while maintaining the metal barrier region on the metal gate in the periphery to the memory array region; and forming a digit line metal on the digit line contact and on the dielectric in which the digit line contact is disposed in the memory array region, while forming material of the digit line metal as a metal contact for and above the metal gate in the periphery to the memory array region.

An example method 12 of forming a memory device can include features of example method 11 of forming a memory device and can include forming a protective dielectric layer on the metal barrier region, with the metal barrier region on the metal gate in the periphery and on the dielectric in the memory array region; forming a photoresist on a portion of the protective layer to provide an open pattern to the memory array region; and removing the metal barrier region from the memory array region while maintaining the metal barrier region on the metal gate.

An example method 13 of forming a memory device can include features of any of the preceding example methods of forming a memory device and can include forming the digit line contact to include: forming an opening in the dielectric in the memory array region, exposing a silicon region in the memory array region; forming polysilicon in the opening to the silicon region, on the memory array region, and above the metal gate in the periphery; removing the polysilicon from the memory array region and from above the metal gate in the periphery such that a portion of the polysilicon remains on the silicon region; and forming the digit line contact on and contacting the portion of the polysilicon that remains on the silicon region.

An example method 14 of forming a memory device can include features of any of the preceding example methods and can include forming a second metal barrier region on the digit line contact, on the dielectric, and on the metal barrier region.

In an example method 15 of forming a memory device, any of the example methods 10 to 15 of forming a memory device may be performed in forming an electronic memory apparatus further comprising a host processor and a communication bus extending between the host processor and the memory device.

In an example method 17 of forming a memory device, any of the example methods 10 to 16 of forming a memory device may be modified to include operations set forth in any other of method examples 10 to 16 of forming a memory device.

In an example method 18 of forming a memory device, any of the example methods 1 to 16 of forming a memory device may be modified to include operations set forth in any other of method examples 1 to 16 of forming a memory device.

In an example method 19 of forming a memory device, any of the example methods 10 to 17 of forming a memory device may be implemented at least in part through use of instructions stored as a physical state in one or more machine-readable storage devices.

An example method 20 of forming a memory device can include features of any of the preceding example methods 10 to 18 of forming a memory device and can include performing functions associated with any features of example memory devices 1 to 15.

An example machine-readable storage device 1 storing instructions, that when executed by one or more processors, cause a machine to perform operations, can comprise instructions to perform functions associated with any features of example memory devices 1 to 15 or perform methods associated with any features of example methods 1 to 20.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a memory array region;
a dielectric disposed in the memory array region;
a digit line contact disposed in the dielectric;
a digit line coupled to the digit line contact by at most one barrier region on the dielectric, the digit line having a metal composition;
a transistor in a periphery to the memory array region;
a metal contact coupled to the transistor, the metal contact having the metal composition of the digit line; and
one or more metal barrier regions above a metal gate of the transistor, coupling the transistor to the metal contact, the one or more metal barrier regions arranged as a unit on and directly contacting the metal gate and directly contacting the metal contact.

2. The memory device of claim 1, wherein the digit line has a thickness equal to a thickness of the metal contact.

3. The memory device of claim 1, wherein the metal composition includes tungsten.

4. The memory device of claim 1, wherein the at most one barrier region includes tungsten silicide extending above and from a top level of the dielectric, and the one or more metal barrier regions include tungsten silicon nitride and tungsten silicide.

5. The memory device of claim 4, wherein the tungsten silicide extends above the top level of the dielectric by about 3 nm and the one or more metal barrier regions combined extends above a top level of the metal gate by about 6 nm.

6. The memory device of claim 1, wherein the digit line is a tungsten digit line without a barrier region above a top level of the dielectric coupling the tungsten digit line to the digit line contact, and the one or more metal barrier regions include tungsten silicon nitride contacting the metal gate and the metal contact.

7. The memory device of claim 6, wherein the tungsten silicon nitride has a thickness of 3 nm.

8. The memory device of claim 1, wherein a step height between a top level of the metal contact on the transistor in the periphery to a top level of the digit line in the memory array region is about 12 nm.

9. The memory device of claim 1, wherein the transistor is a transistor of a complementary metal oxide semiconductor (CMOS) device.

10. The memory device of claim 9, wherein the metal gate is a high-k metal gate.

11. A method of forming a memory device, the method comprising:
forming a memory array region with a dielectric disposed in the memory array region;
forming a digit line contact in the dielectric;
forming a digit line coupled to the digit line contact by at most one barrier region on the dielectric, the digit line having a metal composition;
forming a metal gate of a transistor in a periphery to the memory array region;
forming a metal contact coupled to the metal gate, the metal contact having the metal composition of the digit line; and
forming one or more metal barrier regions above the metal gate of the transistor, coupling the metal gate to the metal contact such that the one or more metal barrier regions, as a unit, are formed on and directly contacting the metal gate and directly contacting the metal contact.

12. The method of claim 11, wherein forming the one or more metal barrier regions includes forming two metal barrier regions.

13. The method of claim 12, wherein forming the two metal barrier regions includes forming a first metal region of the two metal barrier regions before forming the digit line contact in the dielectric and forming a second metal region of the two metal barrier regions after forming the digit line contact in the dielectric.

14. The method of claim 11, wherein forming the digit line is performed in a common fabrication procedure with forming the metal contact.

15. The method of claim 11, wherein the method includes:
forming the digit line and the metal contact using tungsten;
forming the at most one barrier region by forming tungsten silicide extending above and from a top level of the dielectric; and
forming the one or more metal barrier regions by forming tungsten silicon nitride and tungsten silicide.

16. The method of claim 11, wherein the method includes:
forming the digit line by forming a tungsten digit line without a barrier region above a top level of the dielectric; and
forming the one or more metal barrier regions by forming tungsten silicon nitride contacting the metal gate and the metal contact.

17. A method of forming a memory device, the method comprising:
forming a memory array region with a dielectric disposed in the memory array region and a metal gate of a transistor in a periphery to the memory array region;
forming a metal barrier region on the metal gate in the periphery and on the dielectric in the memory array region;
removing the metal barrier region from the memory array region while maintaining the metal barrier region on the metal gate;
forming a digit line contact in the dielectric while maintaining the metal barrier region on the metal gate in the periphery to the memory array region; and
forming a digit line metal on the digit line contact and on the dielectric in which the digit line contact is disposed in the memory array region, while forming material of the digit line metal as a metal contact for and above the metal gate in the periphery to the memory array region.

18. The method of claim 17, wherein the method includes:
forming a protective dielectric layer on the metal barrier region, with the metal barrier region on the metal gate in the periphery and on the dielectric in the memory array region;
forming a photoresist on a portion of the protective layer to provide an open pattern to the memory array region; and
removing the metal barrier region from the memory array region while maintaining the metal barrier region on the metal gate.

19. The method of claim 17, wherein forming the digit line contact includes:
forming an opening in the dielectric in the memory array region, exposing a silicon region in the memory array region;
forming polysilicon in the opening to the silicon region, on the memory array region, and above the metal gate in the periphery;
removing the polysilicon from the memory array region and from above the metal gate in the periphery such that a portion of the polysilicon remains on the silicon region; and
forming the digit line contact on and contacting the portion of the polysilicon that remains on the silicon region.

20. The method of claim 17, wherein the method includes forming a second metal barrier region on the digit line contact, on the dielectric, and on the metal barrier region.
